(19) United States
(12) Patent Application Publication
(10) Pub. No.: US 2021/0218346 A1
(43) Pub. Date: Jul. 15, 2021

(54) INVERTER SYSTEM WITH MINIMUM OUTPUT FILTER

(71) Applicants: Yanchao Li, CULVER CITY, CA (US); Ruigang Li, LOS ANGELES, CA (US); Zheng Zuo, LOS ANGELES, CA (US)

(72) Inventors: Yanchao Li, CULVER CITY, CA (US); Ruigang Li, LOS ANGELES, CA (US); Zheng Zuo, LOS ANGELES, CA (US)

(73) Assignee: AZ Power, Inc, CULVER CITY, CA (US)

(21) Appl. No.: 17/151,099

(22) Filed: Jan. 15, 2021

Related U.S. Application Data
(60) Provisional application No. 62/961,677, filed on Jan. 15, 2020.

(51) Int. Cl. H02M 7/5387; H03K 17/13; H03H 7/09

(52) U.S. Cl. CPC H02M 7/53871; H02M 2001/0003; H03H 7/09; H03K 17/133

(57) ABSTRACT

In one aspect, a power converter may include a plurality of inductor banks; a plurality of capacitor banks; an intermediate bus capacitor bank; a plurality of switches, each switch has a first power node and a second power node, and one control node that receives a control signal that maintains the switch in either ON state in which the circuit path between the first node and the second node are established, or OFF state in which the circuit path between the first node and the second node are eliminated; and a control logic that generates a plurality of signal combinations that are applied to the control nodes of said plurality of switches to enable the power converter to have a smooth voltage output and enhanced tolerance for a low voltage input bus for all signal combinations.

### CROSS-REFERENCE TO RELATED APPLICATIONS

This application claims priority under 35 U.S.C. § 119 (e) to U.S. Provisional Patent Application Ser. No. 62/961,677, filed on Jan. 15, 2020, the entire contents of which are hereby incorporated by reference.

### FIELD OF THE INVENTION

The present invention relates to DC-AC power converters, and more particularly to DC-AC power converters with minimum output filters.

### BACKGROUND OF THE INVENTION

Power inverter is a power electronic device that convert direct current (DC) to alternative current (AC). Power inverters are broadly used, such as in photovoltaic application and electric motor drive application. With sinusoidal pulse width modulation (SPWM) method, the conventional two-level inverter get power from a constant DC voltage source and generate an AC voltage whose magnitude is lower than the magnitude of the DC voltage source. Two paralleled half-bridges are used in a one-phase converter, and three paralleled half-bridges are used in a three-phase converter. A two-level converter produces two different voltage levels at the output node of each half-bridge. In order to get the AC voltage at the output side of the inverter, low pass filters are needed in the circuit.

### SUMMARY OF THE INVENTION

In one aspect, a power converter in the present invention may include a plurality of inductor banks, and each inductor bank has respective first and second node that are connected to respective circuit nodes in a circuit; a plurality of capacitor banks, each capacitor bank has respective first and second node that are connected to respective circuit nodes in a circuit; a plurality of switches, and each switch has two power nodes and one control nodes that receives a control signal that maintains the switch in either ON state in which the circuit path between the first node and the second node are established, or OFF state in which the circuit path between the first node and the second node are eliminated, and the first and second node that are connected to respective circuit nodes in a circuit; and a control logic that generates multiple signal combinations that are applied to the control nodes of the switches so that for each signal combination the device achieves different voltage output.

Particular embodiments of the subject matter described in the present invention can be implemented so as to realize one or more of the following advantages. The power converter in the present invention generates continuous voltage levels between the output nodes with either one-phase or three-phase configurations. In addition, the power converter overcomes the weakness of the conventional two-level inverters who suffer from poor high electromagnetic interference (EMI) issues. Furthermore, with the continuous output voltage, the bulky output low pass filter that is needed to smoothen the output voltage can be significantly reduced, or even eliminated. Also, the total harmonic distortion (THD) specification can be greatly improved. Finally, with the inductor and capacitor resonant circuits in the second-stage circuit, the converter can achieve zero current switching during the operation, which brings the converter great benefit in terms of EMI and efficiency.

The details of one or more embodiments of the subject matter described in this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1. illustrates the circuit diagram of a 2-stage single phase DC to AC converter topology.

FIG. 2 illustrates the circuit diagram of the first stage circuit of the circuit shown in FIG. 1.

FIG. 3 illustrates the circuit diagram of the second stage circuit of the circuit shown in FIG. 1.

FIG. 4 illustrates the circuit diagram of the first active circuit of the second stage circuit shown in FIG. 3.

FIG. 5 illustrates the circuit diagram of the second active circuit of the second stage circuit shown in FIG. 3.

FIG. 6 illustrates the circuit diagram of the third active circuit of the second stage circuit shown in FIG. 3.

FIG. 7 illustrates the circuit diagram of the fourth active circuit of the second stage circuit shown in FIG. 3.

FIG. 8 illustrates the circuit diagram of the fifth active circuit of the second stage circuit shown in FIG. 3.

FIG. 9 illustrates the circuit diagram of the sixth active circuit of the second stage circuit shown in FIG. 3.

FIG. 10 illustrates the output voltage waveform of the two-stage single phase converter.

### DETAILED DESCRIPTION OF THE INVENTION

The detailed description set forth below is intended as a description of the presently exemplary device provided in accordance with aspects of the present invention and is not intended to represent the only forms in which the present invention may be prepared or utilized. It is to be understood, rather, that the same or equivalent functions and components may be accomplished by different embodiments that are also intended to be encompassed within the spirit and scope of the invention.

Unless defined otherwise, all technical and scientific terms used herein have the same meaning as commonly understood to one of ordinary skill in the art to which this invention belongs. Although any methods, devices and materials similar or equivalent to those described can be used in the practice or testing of the invention, the exemplary methods, devices and materials are now described.

All publications mentioned are incorporated by reference for the purpose of describing and disclosing, for example, the designs and methodologies that are described in the publications that might be used in connection with the presently described invention. The publications listed or discussed above, below and throughout the text are provided solely for their disclosure prior to the filing date of the present application. Nothing herein is to be construed as an admission that the inventors are not entitled to antedate such disclosure by virtue of prior invention.

As used in the description herein and throughout the claims that follow, the meaning of “a”, “an”, and “the” includes reference to the plural unless the context clearly dictates otherwise. Also, as used in the description herein and throughout the claims that follow, the terms “comprise or comprising”, “include or including”, “have or having”, “contain or containing” and the like are to be understood to be open-ended, i.e., to mean including but not limited to. As used in the description herein and throughout the claims that follow, the meaning of “in” includes “in” and “on” unless the context clearly dictates otherwise.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the embodiments. As used herein, the term “and/or” includes any and all combinations of one or more of the associated listed items.

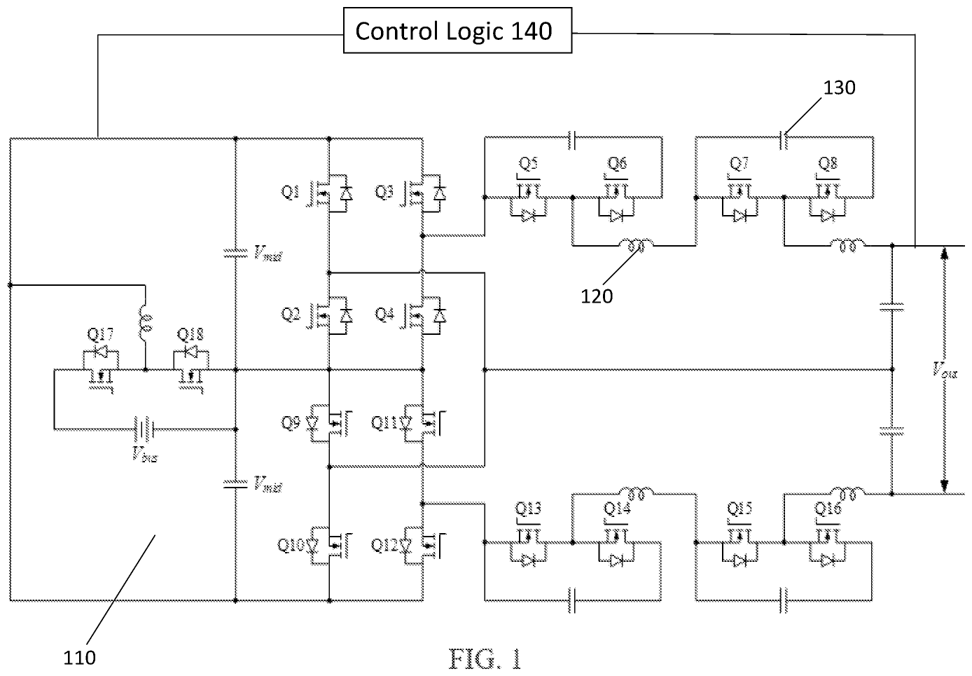

FIG. 1 is circuit diagram of a two-stage single phase DC to AC converter topology. This circuit is constructed on a circuit bearing structure, such as print circuit board (PCB).

The power converter includes a plurality of intermediate dc bus capacitor banks 110. With properly designed intermediate bus capacitor banks, the voltage between the first stage circuit and the second stage circuit could change smoothly, and the capacitor banks have respective first and second nodes connected to respective circuit node in the circuit. The circuit also includes a plurality of inductor banks 120 and capacitor banks 130. Each inductor/capacitor bank may include at least one inductor/capacitor, and each inductor/capacitor bank has a first and second nodes. In some embodiments, an inductor in an inductor bank may be the parasitic inductance of a circuit bearing structure. The circuit also includes a plurality of switches Q1 to Q18 that have respective first and second power nodes and a control node. The input of control signal maintains the switch in either ON state in which the circuit path between the first node and the second node are established, or OFF state in which the circuit path between the first node and the second node are eliminated. As shown in FIG. 1, in one embodiment, N-channel MOSFETs are used. However, any other types of switches can be also used. The power converter may also include a control logic 140.

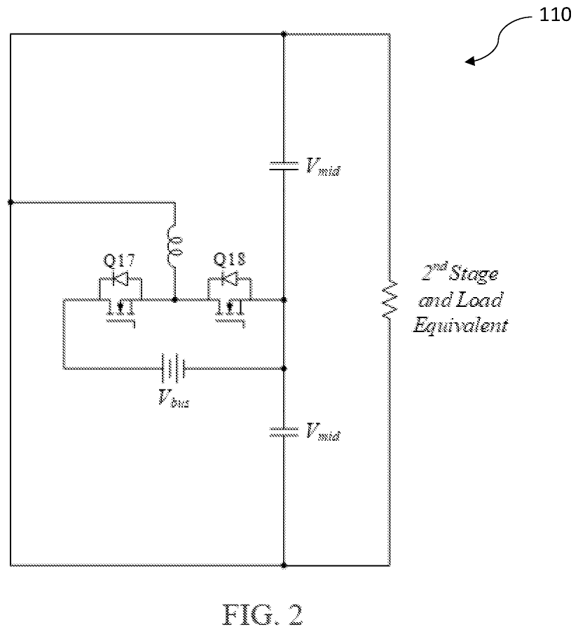

FIG. 2 is the circuit diagram of the first stage circuit of the circuit shown in FIG. 1. The function of the first stage circuit is to obtain power from the low voltage source and generate a continuous changing voltage on the intermediate DC bus, which is achieved by adjusting duty cycle of the control signals that are generated by control logic. The first stage circuit have fine voltage regulation capability.

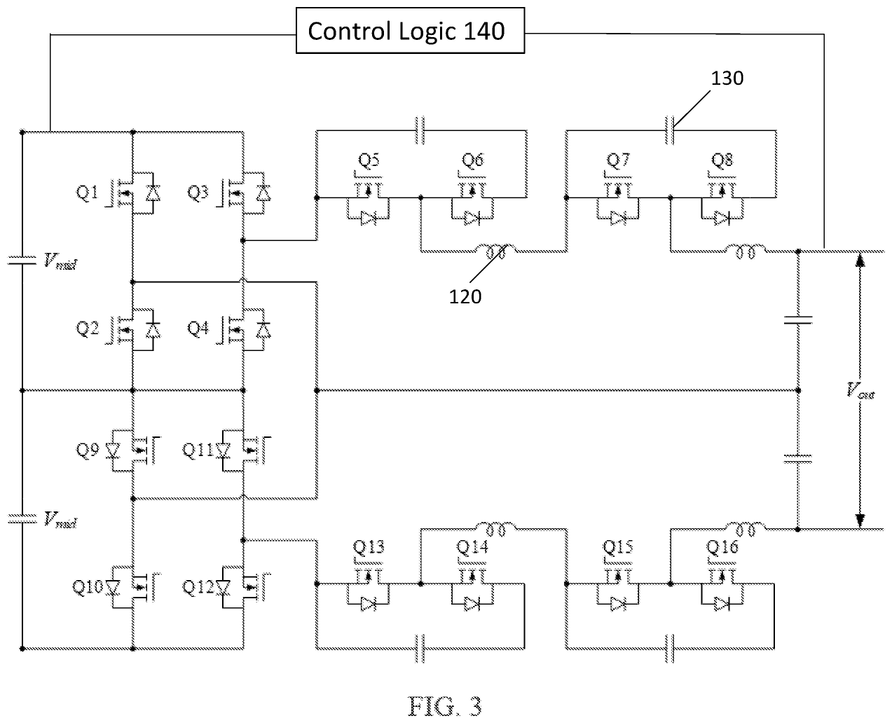

FIG. 3 is the circuit diagram of the second stage circuit of the circuit shown in FIG. 1. By using control signals from the control logic, the second stage circuit alone can generate limited different voltage levels at the circuit output while getting a constant voltage from its input. The second stage circuit have rough voltage regulation capability.

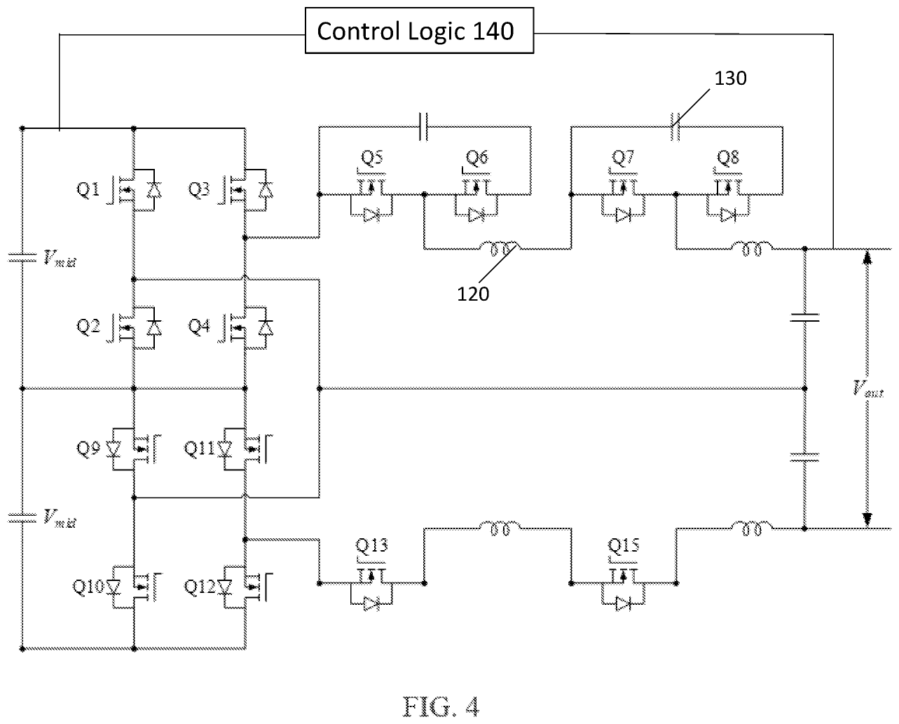

FIG. 4 is the circuit diagram of the first active circuit of the second stage circuit shown in FIG. 3. When both capacitor banks in the top half of the circuits are actively kick in and kick out during the converter operation, and both capacitor banks in the bottom half of the circuits are bypassed, the second stage circuit generates voltage that has magnitude+3 V_{MID} at the output.

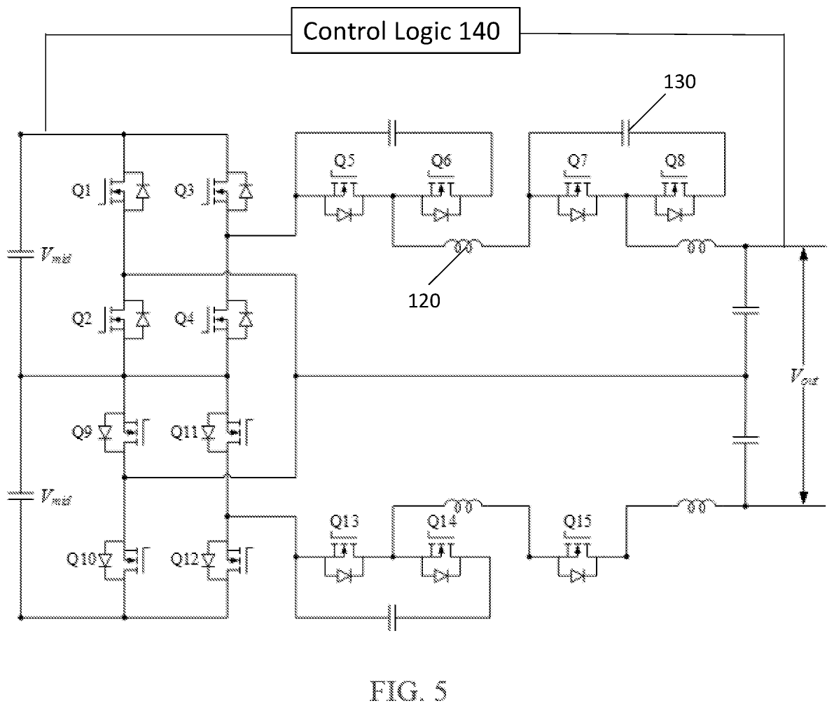

FIG. 5 is the circuit diagram of the second active circuit of the second stage circuit shown in FIG. 3. When both capacitor banks in the top half of the circuits are actively kick in and kick out during the converter operation, one of the capacitor banks in the bottom half of the circuits are active and one of the capacitor banks in the bottom half of the circuits are bypassed, the second stage circuit generates voltage that has magnitude+2 V_{MID} at the output.

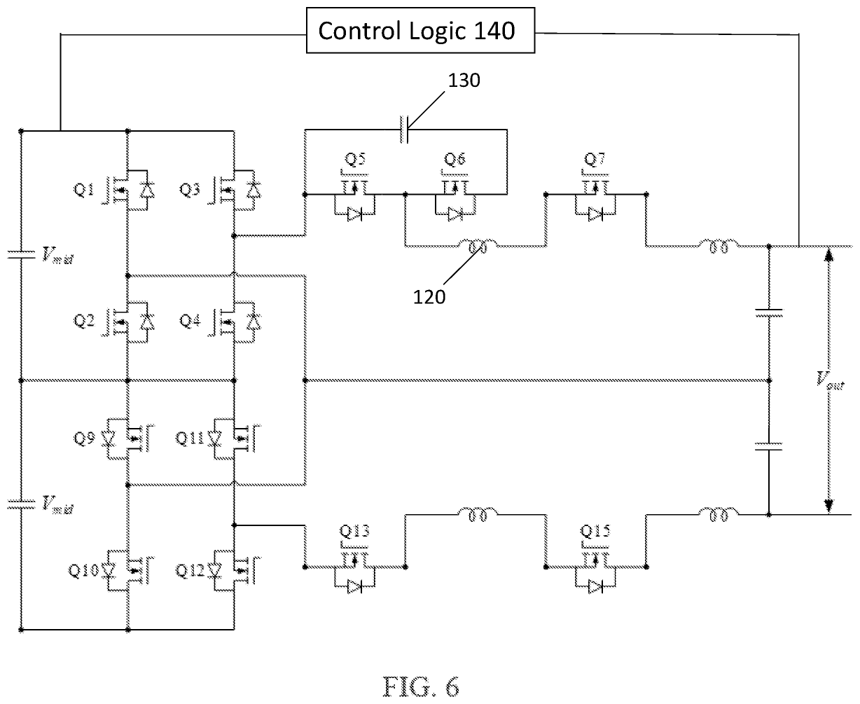

FIG. 6 is the circuit diagram of the third active circuit of the second stage circuit shown in FIG. 3. When one of the capacitor banks in the top half of the circuits are actively kick in and kick out during the converter operation, one of the capacitor banks in the top half of the circuits are bypassed and both capacitor banks in the bottom half of the circuits are bypassed, the second stage circuit generates voltage that has magnitude+1V_{MID} at the output.

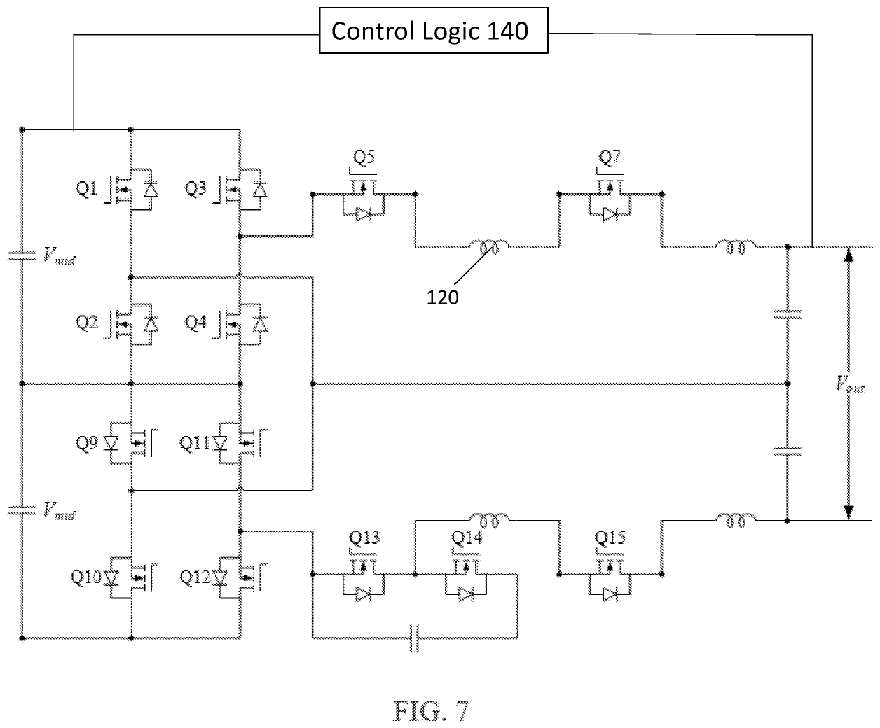

FIG. 7 is the circuit diagram of the fourth active circuit of the second stage circuit shown in FIG. 3. When one of the capacitor banks in the bottom half of the circuits are actively kick in and kick out during the converter operation, one of the capacitor banks in the bottom half of the circuits are bypassed and both capacitor banks in the top half of the circuits are bypassed, the second stage circuit generates voltage that has magnitude −1V_{MID} at the output.

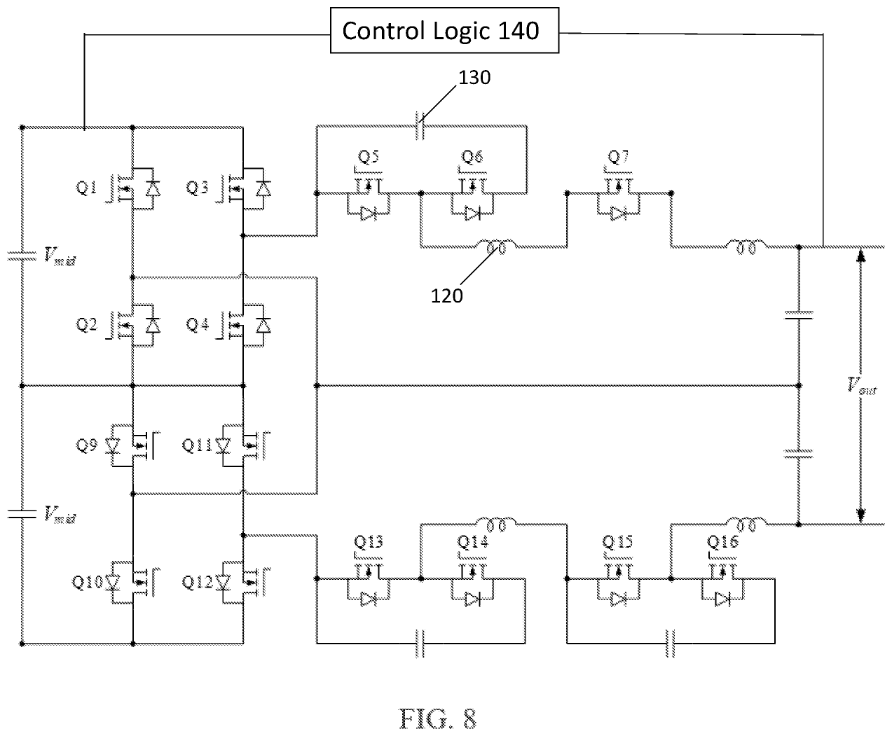

FIG. 8 is the circuit diagram of the fifth active circuit of the second stage circuit shown in FIG. 3. When both capacitor banks in the bottom half of the circuits are actively kick in and kick out during the converter operation, one of the capacitor banks in the top half of the circuits are active and one of the capacitor banks in the top half of the circuits are bypassed, the second stage circuit generates voltage that has magnitude −2V_{MID} at the output.

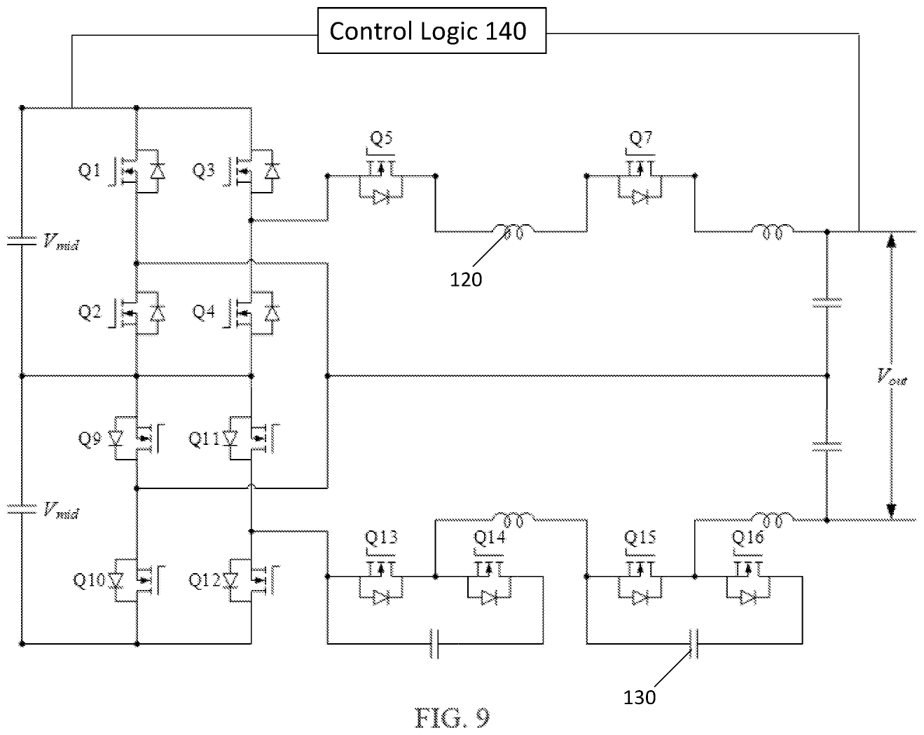

FIG. 9 is the circuit diagram of the sixth active circuit of the second stage circuit shown in FIG. 3. When both capacitor banks in the bottom half of the circuits are actively kick in and kick out during the converter operation, and both capacitor banks in the top half of the circuits are bypassed, the second stage circuit generates voltage that has magnitude −3 V_{MID} at the output.

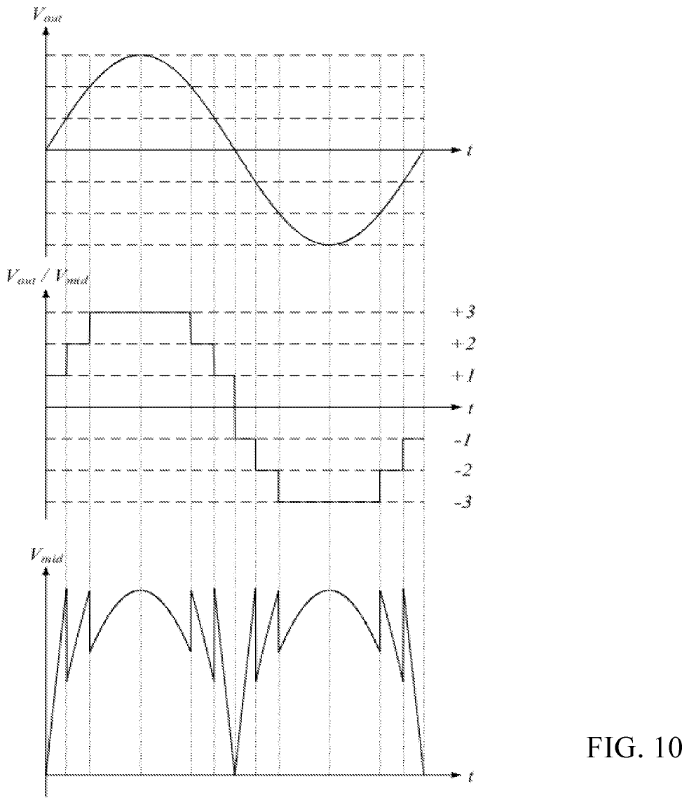

FIG. 10 is the output voltage waveforms of the two-stage converter and the first stage circuit. When the voltage output of first stage circuit V_{MID} follow the specific pattern, and the voltage output ratio of the two-stage converter output V_{OUT} and intermediate bus voltage V_{MID} are synchronized in a timely manner, sinusoidal voltage is generated by the two-stage converter.

In some implementations, the control logic controls the second stage switches to turn-on and turn-off at zero current, therefore the zero current switching is achieved. This control mechanism gives the lossless switching feature to the part of the circuit.

In summary, the present invention relates to an inverter system with minimum output filter. The inverter system is a two-stage system that mat include multiple switches that are connected to the circuit nodes; multiple inductor and capacitor banks that are connected to the non-ground circuit nodes; and multiple intermediate dc bus capacitor banks that are connected to the positive and negative nodes of the intermediate bus. The switches are controlled by the control logic that generates different control signals which are applied to the control nodes of the switches. For each set of control signal combination, the second stage circuit can generate different voltage levels at the converter output. Together with the first stage circuit, the converter generates smooth sinusoidal voltage at the converter output. In addition, the control logic generates signals to ensure the switches in the second stage circuit to turn on and off at zero current.

Having described the invention by the description and illustrations above, it should be understood that these are exemplary of the invention and are not to be considered as limiting. Accordingly, the invention is not to be considered as limited by the foregoing description, but includes any equivalent.

What is claimed is:

1. A power converter comprising:
a plurality of inductor banks;
a plurality of capacitor banks;
an intermediate bus capacitor bank;
a plurality of switches, each switch has a first power node and a second power node, and one control node that receives a control signal that maintains the switch in either ON state in which the circuit path between the first node and the second node are established, or OFF state in which the circuit path between the first node and the second node are eliminated; and
a control logic that generates a plurality of signal combinations that are applied to the control nodes of said plurality of switches to enable the power converter to have a smooth voltage output and enhanced tolerance for a low voltage input bus for all signal combinations.

2. The power converter of claim 1, wherein each inductor bank includes at least one inductor that have two nodes that are connected to respective circuit nodes in a circuit, and each capacitor bank includes at least one capacitor that have two nodes that are connected to respective circuit nodes in a circuit.

3. The power converter of claim 1, wherein each first power node and each second power node of each switch is connected to a respective circuit node in the circuit.

4. The power converter of claim 1, wherein the control logic generates control signals to cause zero current switching on each switch in the circuit.

5. The power converter of claim 1, wherein inductor in an inductor bank is a parasitic inductance of a circuit bearing structure.

6. The power converter of claim 1, wherein the switches are MOSFETs, the first power nodes are drains and the second power nodes are sources, and the control nodes are gates.

7. The power converter of claim 1, wherein the capacitor bank that have two nodes connected to respective circuit nodes in a circuit.

8. The power converter of claim 1, wherein at least one circuit node connects with an input voltage and at least one circuit node connects with an output voltage.
